(19) United States
(12) Patent Application Publication
(10) Pub. No.: US 2011/0300692 A1
(43) Pub. Date: Dec. 8, 2011

(54) METHOD FOR DIVIDING A SEMICONDUCTOR FILM FORMED ON A SUBSTRATE INTO PLURAL REGIONS BY MULTIPLE LASER BEAM IRRADIATION

(75) Inventors: Jens Günster, Sargans (CH); Ivan Sinicco, Pfaffikon (CH)

(73) Assignee: OERLIKON SOLAR AG, TRUBBACH, Trubbach (CH)

(21) Appl. No.: 13/126,487

(22) PCT Filed: Oct. 20, 2009
(86) PCT No.: PCT/CH2009/000336

§ 371 Date: Aug. 12, 2011

Related U.S. Application Data
(60) Provisional application No. 61/109,280, filed on Oct. 29, 2008.

(51) Int. Cl. H01L 21/268; B29C 35/08

(52) U.S. Cl. 438/463; 425/174.4; 257/E21.347

(57) ABSTRACT

The present invention relates to a method for dividing a semiconductor film formed on a substrate into plural regions by multiple laser beam irradiation using a sequence of at least two laser beam treatments affecting essentially a same area of said film. Except of a final laser beam treatment, the treatments of said sequence of at least two laser beam treatments are used for a conditioning of the treated film area which is to be removed. Said final laser beam treatment is applied to actually remove material in order to form a groove. Further, the invention relates to an arrangement for dividing a semiconductor film formed on a substrate into plural regions by multiple laser beam irradiation using a sequence of at least two laser beam treatments affecting essentially a same area of said film. Said arrangement comprises a first conditioning laser for the treatments of said sequence of at least two laser beam treatments except of a final laser beam treatment and it comprises a second laser for said final laser beam treatment.

### TECHNICAL FIELD

The invention relates to a method for dividing a semiconductor film formed on a substrate into plural regions by multiple laser beam irradiation using a sequence of at least two laser beam treatments affecting essentially a same area of said film.

### BACKGROUND ART

Nowadays, various solar cell technologies are commercially available. Amongst them, thin film solar cells which employ thin amorphous and/or microcrystalline silicon films are actively being developed. The possibility to process a plurality of such cells at low temperatures and on large areas (>1 m²) brings this technology in favour as a good candidate to achieve the so-called grid parity.

FIG. 1 shows a schematic cross section of a portion of a conventional photovoltaic module 1 comprising several thin film solar cells according to the prior art. On a transparent, insulator substrate 2, a transparent (front) electrode layer 3 is being arranged. On said transparent (front) electrode layer 3, a photoelectric conversion semiconductor layer 4 is formed and on the latter one a further transparent (back) electrode layer 5 is formed. Said photoelectric conversion semiconductor layer 4 comprises a stack of amorphous and/or microcrystalline silicon sublayers.

Further, FIG. 1 shows in these three layers 3, 4, 5 three different types of grooves 6, 7, 8 which structure the plane of the photovoltaic module. The purpose of this structuring is to establish a photovoltaic module composed of a number of thin film solar cells electrically connected in series. Said transparent (front) electrode layer 3 is divided by a set of first isolation grooves 6 which determine the width of the individual thin film solar cells. Said photoelectric conversion semiconductor layer 4 is filling said first insulation grooves 6, when the stack of said three layers 3, 4, 5 is being built up during the manufacturing process in the order: transparent (front) electrode layer 3, first isolation grooves 6 photoelectric conversion semiconductor layer 4, grooves 7, further transparent (back) electrode layer 5 second isolation grooves 8. Said grooves 7, filled with material of said transparent (back) electrode layer 5 permit the electrical contact between the adjacent cells. In fact said transparent (back) electrode layer 5 of one cell contacts said transparent (front) electrode layer 3 of the adjacent cell. Said transparent (back) electrode layer 5 and said photoelectric conversion semiconductor layer 4 are finally divided by a set of said second isolation grooves 8. This structuring process is achieved preferably by employing a laser light or the like.

Said thin film photovoltaic module 1 can be fabricated for example as follows: Initially, said transparent (front) electrode layer 3 is deposited on said transparent insulator substrate 2, e.g. by means of LPCVD (low pressure chemical vapour deposition). Said transparent (front) electrode layer 3, also called transparent conductive oxide (TCO, e.g. consisting of ZnO, SnO₂ or Indiumtinoxide), is thereafter laser-scribed to remove a portion of said transparent (front) electrode layer 3 to form a first set of said isolation grooves 6 dividing said transparent (front) electrode layer 3 into a plurality of isolated, laterally adjacent regions. Subsequently, over this patterned transparent (front) electrode layer 3, a plasma chemical vapour deposition is employed to deposit said photoelectric conversion layer 4. Said photoelectric conversion layer 4 comprises at least one p-doped sublayer, one intrisically insulating sublayer and one n-doped sublayer of e.g. amorphous silicon. This stack of sublayers can be repeated in order to form multijunction amorphous silicon thin film solar cells. Thus, a second, a third and even more p-i-n junctions can be formed from microcrystalline materials or a mixture from amorphous and microcrystalline materials in order to establish said photoelectric conversion semiconductor layer 4. Said photoelectric conversion semiconductor layer 4 is then laser-scribed in order to remove a portion of said photoelectric conversion semiconductor layer 4 to form a set of grooves 7 (later: contact lines 9) which divide said photoelectric conversion semiconductor layer 4 into a plurality of regions that are laterally separated from each other. Subsequently, said transparent (back) electrode layer 5 is deposited to fill said grooves 7 and thereby resulting into said contact lines 9 and also to cover said photoelectric conversion semiconductor layer 4. Said transparent (back) electrode layer 5 can again be a transparent conductive oxide (TCO e.g. consisting of ZnO, SnO₂ or Indiumtinoxide). Finally, said photoelectric conversion semiconductor layer 4 and said transparent (back) electrode layer 5 are laser-scribed forming a set of second isolation grooves 8 that divide said photoelectric conversion semiconductor layer 4 laterally into a plurality of photoactive regions electrically connected in series. This way, said photovoltaic module 1 comprising thin film solar cells as shown in FIG. 1 is fabricated.

A method of manufacture using a scribing laser is disclosed in U.S. Pat. No. 4,292,092, U.S. Publication 2005/0272175, WO 2008/019066. Despite the known advantages of laser scribing for the manufacturing process of photovoltaic modules comprising serial connected thin film solar cells, laser-caused problems are known to occur in zones adjacent to the laser-treated parts of the photovoltaic modules. For some materials, conductive ridges or “collars” are left along the edges of the laser scribed lines or grooves. In addition, melted residues at the bottom of scribed grooves may introduce electrical short circuits, poor isolation between adjacent thin film solar cells and low shunt resistance reducing the voltage integration over an array of serial connected thin film solar cells. In state-of-the-art laser treatments for the described purpose, normally a laser source is being used which has an output power exceeding the calculated physically necessary power. This is done to assure that the above mentioned problems like melted remains of removed materials are avoided. These high-power lasers are expensive and require additional efforts in the optical path, measurement and so forth. A method to avoid these problems and thus improving the voltage integration of serial connected thin film solar cells is disclosed in WO 2008/019066 A2. Therein, it is described to allow a primary laser beam to pass a first time along a line to form a groove with a first and a second edge. Subsequently, the laser beam passes one or more times more approximately along the same line and improves the level of the electrical isolation between said first and said second edge, thus forming said photovoltaic module comprising said plurality of thin film solar cells.

### SUMMARY OF THE INVENTION

It is the object of the invention to create a method for dividing a semiconductor film formed on a substrate into plural regions by multiple laser beam irradiation pertaining to the technical field initially mentioned that allows to lower the power of the used laser systems and that reduces or even avoids laser-caused problems which are known to occur in zones adjacent to laser-treated parts of materials.

The solution of the invention is specified by the features of claim 1. According to the invention, the treatments of a sequence of at least two laser beam treatments with the exception of a final laser beam treatment are used for a conditioning of the treated film area which is to be removed, while said final laser beam treatment is applied to actually remove material in order to form a groove.

Said final laser beam treatment may preferably be performed as a single laser beam treatment step, but could, following the teachings of WO 2008/019066 A2, also be employed in form of a removal in more than one treatment step.

Lasers that are for the invention useful to work with include continuous wave or pulsed lasers, preferably continuous wave or long pulsed lasers with a pulse duration of more than 100 ns. Their power should be between 0.5 and 10 W in the focus of the beam on the substrate. Appropriate wavelengths are 255 nm, 532 nm and 1064 nm (+/−50 nm).

The advantage of this solution is a resulting side wall of said groove which is steeper and smoother than obtained by prior art methods. Additionally, said groove can be scribed faster and with better accuracy. Furthermore, conductive ridges or “collars” left along the edges of the laser scribed lines or grooves are avoided as well as melted residues at the bottom of scribed grooves which may introduce electrical short circuits, a poor isolation between adjacent thin film solar cells and a low shunt resistance reducing the voltage integration over an array of serial connected thin film solar cells are avoided.

Preferably, an arrangement according to the invention comprises a first conditioning laser for the treatments of said sequence of at least two laser beam treatments except of a final laser beam treatment and comprises a second laser for said final laser beam treatment. This allows for an optimal separation of the step of said conditioning of the treated film area which is to be removed and of the step of a removal of the conditioned material in order to form said groove.

Alternatively, in the context of the inventive method said first conditioning laser and said second laser may be incorporated into a same laser which provides two different working modes, i.e. a first working mode for conditioning of said treated film area and a second working mode for removing the material of said treated film area.

Preferably, except of said final laser beam treatment, essentially no matter shall be removed via ablation/evaporation by previous treatments of said sequence of said at least two laser beam treatments. In particular, no groove forming a first and a second edge separated by said groove, providing a first level of electrical insulation, is formed by said previous treatments. This has the advantage that said previous treatments change the material properties of said film locally, e.g. anneal said film. This conditioning is comparable to a “marking” of said groove. This procedure induces a thermal stress track in said film, within which said final laser beam treatment scribes said groove, thus dividing said film in said plurality of regions.

Alternatively, said previous treatments could already remove some matter, whereas however the principal part of the matter is removed during the final laser beam treatment.

Advantageously, a first laser beam treatment is followed by a second, third and so on within a time window of 0.01 to 1000 ms, preferably 0.1 to 100 ms. Using a higher number of laser treatments has the advantage that said conditioning of said material in said treated film area which is to be removed can be performed with increasing number of conditioning treatments with a laser of decreasing power. This is economic, since a less powerful laser can be used. The choice of said time window has the advantage that the conditioning process is optimised between a distribution in said material of the energy which is deposited by one conditioning treatment and a reasonable cadence of the treatments such that the dividing of said film is obtainable with an optimal speed.

Preferably, a first conditioning laser beam is generated by a continuous wave laser and a second laser beam is generated by a pulsed laser. This has the advantage that the type of the laser beam used for the respective purpose is optimally adapted to the requirements of the respective purpose.

Alternatively, both laser beams could be generated either by a pulsed laser or by a continuous wave laser. As a further alternative, said first conditioning laser beam could be generated by a pulsed laser and said second laser beam could be generated by a continuous wave laser.

Advantageously, said substrate is moved in one direction on a table-like arrangement for supporting said substrate. This one directional movement has the advantage that the actuation of the movement is simple and that it can be easily obtained with a high precision and at the same time in a cost effective way. As an alternative, said substrate may also be moved on said table-like arrangement for supporting said substrate in the entire plane of the substrate instead of only in one direction.

Preferably, the substrate is moved on an air cushion on said table-like arrangement as disclosed in WO 2005/118440 A1 which is incorporated herein by reference in its entirety. Preferably, a first conditioning laser which is mounted on a carriage is used to perform a conditioning step and a second laser which is mounted on said carriage and which is arranged spaced apart of said first conditioning laser in a line oriented along a movement direction of said carriage is used to perform a removal step. This allows for an optimal separation of said conditioning step of the treated film area which is to be removed and of said removal step in order to form said groove. Further, it has the advantage that the lasers used for the respective steps can optimally be adapted to the requirements of the respective steps. Additionally, said conditioning step and said removal step can be performed during a single movement of said carriage, which is time saving and thus cost effective.

Advantageously, a bidirectional functionality of the laser arrangement is achieved by using a further conditioning laser installed on said carriage in said line with said first conditioning laser and said second laser. This has the advantage that said carriage can be moved along either direction of said movement direction while treating said film. Consequently, a treatment of a large film area where more than one groove has to be made can be performed in a timesaving way.

Alternatively, the carriage could be reoriented for making a groove during a movement in a different direction than the direction of the initial movement.

Preferably, any region of said substrate is treated by moving said substrate on said table-like arrangement along said one direction and by moving said carriage with the laser arrangement along said movement direction which is oriented crosswise to said one direction. This has the advantage that the entire area of said film can be treated while the actuation of both said movement direction and said one direction can be kept one directional and can thus be kept simple. Accordingly, the realisation of the two movements is cost effective and requires little maintenance effort.

Preferably, said groove is made parallel to said movement direction and said line. This has the advantage that within one movement of said carriage along said movement direction, both said conditioning step and said removal step can be performed. Accordingly, said groove is made in a time saving and thus cost effective way.

Advantageously, a laser beam is irradiated from another main surface of said substrate which is light transmissive, through said substrate to said same area of the respective said film, thus dividing/segmenting said film into said plurality of regions. This may increase the quality of the formed grooves as the ejection of the removed material is improved.

Alternatively, said laser beam can be irradiated from the direction of the same main surface of said substrate as said film is located.

Preferably, said groove is made in said film in that said carriage is moved along said movement direction in either direction and said second laser and the one of said first conditioning laser and said further conditioning laser which is in front of said second laser as seen in the moving direction of said carriage are running, such that any point on said same area of said film, where said groove is to be made, is first treated with either said first conditioning laser or said further conditioning laser and subsequently treated with said second laser. This has the advantage that both said conditioning step and said removal step can be performed within a movement of said carriage along either direction of said movement direction. Accordingly, said groove can be made in a time saving and thus cost effective way.

Advantageously, said substrate is moveable in one direction on said table-like arrangement for supporting said substrate. This one directional manoeuvrability has the advantage that the actuation of said substrate on said table-like arrangement is simple and that it can be easily obtained with a high precision and at the same time in a cost effective way. As an alternative, said substrate could also be moveable in the entire plane of the substrate on said table-like arrangement for supporting said substrate instead of in only one direction.

Preferably, the substrate is moveable on an air cushion on said table-like arrangement as shown in WO 2005/118440 A1 which is incorporated herein by reference in its entirety. Advantageously, a carriage accommodating a plurality of lasers comprises at least said first conditioning laser and, spaced apart but arranged in a line with a movement direction of the first conditioning laser, said second laser. This has the advantage that a conditioning step and a removal step can be performed during a single movement of said carriage, which is time saving and thus cost effective.

Preferably, said carriage can comprise a further conditioning laser arranged in said line with said first conditioning laser and said second laser in order to allow for a bidirectional functionality of said laser arrangement. This has the advantage that a treatment of a large film area where more than one groove has to be made can be performed in a time saving way by moving said carriage along either direction of said movement direction.

Alternatively, the carriage may be reorientable for making a groove during a movement in a different direction than the direction of the initial movement.

Advantageously, said first conditioning laser is a continuous wave laser and said second laser is a pulsed laser. This has the advantage that the type of the laser used for the respective purpose can be optimally adapted to the requirements of the particular purpose.

Alternatively, both lasers could be pulsed lasers or continuous wave lasers. As a further alternative, said first conditioning laser could be a pulsed laser and said second laser could be a continuous wave laser.

Preferably, said first conditioning laser and said further conditioning laser are identical and said first conditioning laser and said further conditioning laser are located at the same distance but in the opposite direction of said second laser. This has the advantage that independent of the direction of the movement of said carriage along said movement direction, the parameters of the lasers and the speed of the movement of said carriage are the same. This simplifies the control of the arrangement during the making of said groove. Accordingly, the development and the production of the arrangement are cost effective.

As an alternative, the distances between the lasers may be varied and the types of said first conditioning laser and said further conditioning laser may be different. An according arrangement on said carriage may be advantageous in the case where there are grooves to be made in different films with different properties. In that case, the same carriage could be used for the treatments of different films.

Advantageously, any region of said substrate is treatable by moving said substrate on said table-like arrangement along said one direction and by moving said carriage with the laser arrangement along said movement direction which is oriented crosswise to said one direction. This has the advantage that the entire area of said film is treatable while the actuation of both said movement direction and said one direction can be kept one directional and can thus be kept simple. Accordingly, the realisation of the arrangement is cost effective and requires little maintenance effort.

Other advantageous embodiments and combinations of features come out from the detailed description below and the totality of the claims.

### BRIEF DESCRIPTION OF THE DRAWINGS

The drawings used to explain the embodiments show:

FIG. 1 An arrangement of layers and laser-scribed grooves according to the prior art,

FIG. 2 an arrangement of the lasers according to the invention;

FIG. 3 an arrangement of the substrate and the lasers with the movement directions indicated; and

FIG. 4 a table-like arrangement as disclosed in WO 2005/118440 A1.

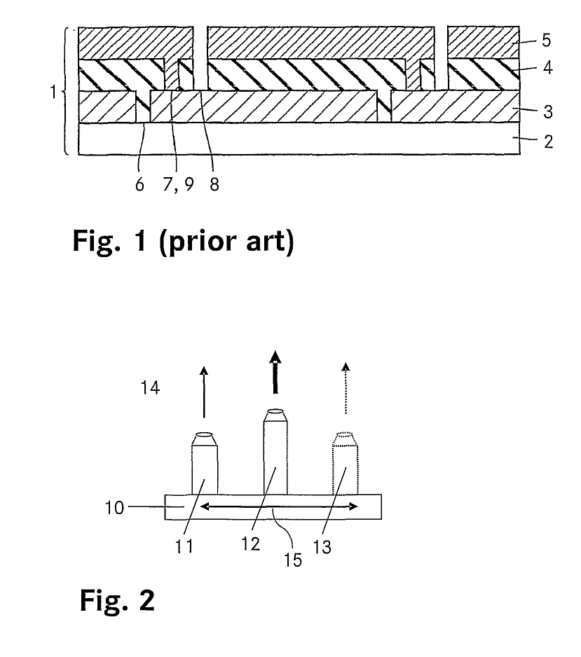

In the figures, the same components are given the same reference symbols.

### PREFERRED EMBODIMENTS

FIG. 2 shows a schematic representation of a carriage 10 accommodating a plurality of lasers. This carriage 10 comprises at least a first conditioning laser 11 configured to perform a conditioning step as described above, and, spaced apart, but arranged in a line with the movement direction of said first conditioning laser 11, a second laser 12 configured to perform a removal step as described above in the invention. In order to allow for a bidirectional functionality of said laser arrangement, i.e. of said carriage 10, a further conditioning laser 13 may be installed on said carriage 10, again in said line with said first conditioning laser 11 and said second laser 12, said line being parallel to a movement direction of said carriage 10, as indicated by the double arrow. The arrows 14 indicate the direction of the laser light.

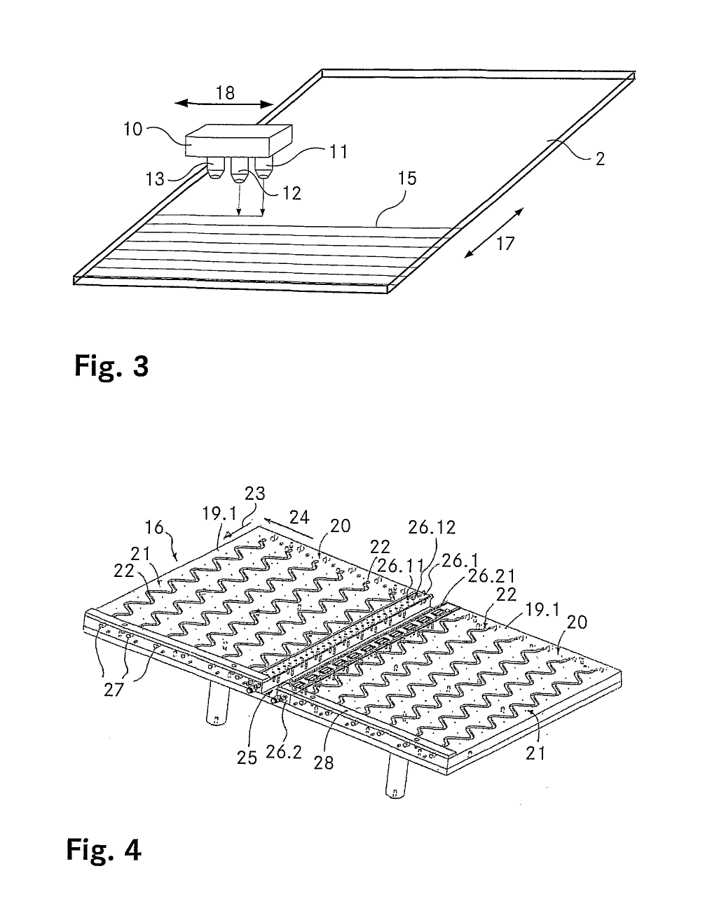

FIG. 3 shows an arrangement according to the invention for dividing a semiconductor film on a transparent insulator substrate 2 into a plurality of regions by scribing a set of grooves 15 into said film. Said transparent insulator substrate 2 has a flat, slab-like shape. It is mounted in a horizontal orientation with said semiconductor film on its lower main surface on a table-like arrangement 16 (shown in FIG. 4). It is moveable along one direction 17 (indicated by a double arrow) which is perpendicular to said grooves 15. Above an upper main surface of said transparent insulator substrate 2, said carriage 10 is mounted with said first conditioning laser 11, said second laser 12 and said further conditioning laser 13 arranged in said line along said grooves 15 and perpendicular to said one direction 17. The light of said first conditioning laser 11, said second laser 12 and said further conditioning laser 13 is directed downwards. Said carriage 10 is moveable along a movement direction 18 (indicated by a double arrow) which is parallel to said line and said grooves 15 and perpendicular to said one direction 16.

The set of said grooves 15 is scribed into said film by moving said carriage 10 for each one of said grooves 15 along said movement direction 18. During this movement, said second laser 12 is running. Additionally, the one of said first conditioning laser 11 and said further conditioning laser 13 is running which is located from said second laser 12 in the direction of the movement of said carriage 10. After said one of said grooves 15 is scribed, said transparent insulator substrate 2 is moved along said one direction 17 by a step corresponding to a distance between two of said grooves 15, while none of said first conditioning laser 11, said second laser 12 and said further conditioning laser 13 is actuated. Subsequently, a next one of said grooves 15 is scribed by moving said carriage 10 along said movement direction 18 with said second laser 12 and either said first conditioning laser 11 or said further conditioning laser 13 actuated.

FIG. 4 shows an embodiment of said table-like arrangement 16 for moving said transparent insulator substrate 2 on an air cushion along said one direction 17 as it can be used for the arrangement of the substrate and the lasers as illustrated in FIG. 3. This particular embodiment is disclosed in WO 2005/118440 A1 which is incorporated herein in its entirety: Said table-like arrangement 16 comprises a tabletop 19 which is divided in a first half 19.1 and a second half 19.2. The upper main surfaces of said first half 19.1 and said second half 19.2 form together a flat supporting area 20 of said table-like arrangement 16 for said transparent insulator substrate 2. Said flat supporting area 20 comprises a large number of jet openings 21 where a fluid (here: air) effuses and comprises a large number of drain openings 22, where at least parts of said fluid on said flat supporting area 20 is aspirated. Said drain openings 22 are channels that form dimples in said flat supporting area 20 and that have a zigzag or snake-like shape along a width 23 of said flat supporting area 20. They are equally spaced distributed along a length 24 of said flat supporting area 20. Their number depends on said length 24 and is chosen to ensure on the entire said flat supporting area 20 a homogeneous aspiration of said fluid. Between said drain openings 22, said jet openings 21 with a round cross section are equally distributed along said width 23 and said length 24 of said flat supporting area 20. The area of said jet openings 21 is considerably smaller than the area of said drain openings 22.

Between said first half 19.1 and said second half 19.2 of said tabletop 19, a linear gap 25 divides said flat supporting area 20 along the entire width 23 into two parts. Between said linear gap 25 and said first half 19.1, a first square 26.1 is attached to said first half 19.1. An upper surface of said first square 26.1 is flush with said upper main surface of said first half 19.1. In the same way, a second square 26.2 is attached to said second half 19.2 between said linear gap 25 and said second half 19.2. An upper surface of said second square 26.2 is flush with said upper surface of said second half 19.2.

In said upper surface of said first square 26.1, two parallel rows 26.11 of equally spaced second jet openings are placed along a length of said first square 26.1, i.e. along said width 23 of said flat supporting area 20. Between said two parallel rows 26.11 of said equally spaced second jet openings, there is one row of second drain openings 26.12 located. The openings of said one row of second drain openings 26.12 have a round cross section with a considerably larger diameter than a diameter of said second jet openings of said two parallel rows 26.11.

In said upper main surface of said second square 26.2, a row of equally spaced openings 26.21 is arranged along a length of said second square 26.2, i.e. along said width 23 of said flat supporting area 20. Said openings 26.21 consist of an inner drain opening with a double-T like shape which is framed by a square-shaped outer jet opening.

All drain openings are connected by a drain system and linked with distraction sockets 27 on a side of said table-like arrangement 16. Said distraction sockets 27 are connected with a pump (not shown) which distracts said fluid through said drain openings. In the same manner, all jet openings are connected via a tube system with a compressor (not shown) which allows for an electronically controlled overpressure regulation and thus for a regulation of a stream of said fluid out of said jet openings.

Said transparent insulator substrate 2 is positioned above said flat supporting area 20 in a horizontal orientation such that the surface with said film is pointing downwards. Said stream of said fluid out of said jet openings produces an air cushion between said flat supporting area 20 and said transparent insulator substrate 2, such that said transparent insulator substrate 2 is floating on top and is moveable along said one direction 17 (oriented along said length 24) on said supporting area 20. The feed of this movement is provided by an actuation system (not shown) affixed to linear guides 28 which are attached to both length side edges of said first half 19.1 and said second half 19.2 of said tabletop 19 (in FIG. 4, said linear guides 28 are only shown on one length side edge in order to keep track of underlying objects). Said actuation system comprises two guide rails which are attached to said linear guides 28. On said two guide rails, four carriages are running. Between a first carriage located on a first one of said two guide rails and a second carriage located on a second one of said two guide rails, a first holder is placed. A second holder is placed between a third carriage located on said first one of said two guide rails and a fourth carriage located on said second one of said two guide rails. Said transparent insulator substrate 2 is placed between said first holder and said second holder and is moved along said one direction 17 by moving said four carriages with said first and said second holder along said two guide rails.

According to the arrangement shown in FIG. 3, said carriage 10 is located above said table-like arrangement 16 such that the light of said first conditioning laser 11, said second laser 12 and said further conditioning lasers 13 is illuminated from above through said transparent insulator substrate onto said film on the lower main surface of said transparent insulator substrate 2.

The invention is not limited to the above mentioned embodiments. Other embodiments are possible as well, namely for example embodiments where more than the mentioned two or three lasers are arranged on said carriage 10. In that case, said second laser 12 and several conditioning lasers can be arranged along said line. Accordingly, said more than one conditioning lasers which are located from said second laser 12 in the direction of the movement of said carriage 10 can be activated. Accordingly, the treatments by said more than one conditioning lasers change the material properties of said film locally, e.g. anneal said film. This procedure induces a thermal stress track in said film, within which said final laser beam treatment by said second laser 12 scribes said groove, thus dividing said film in said plurality of regions. In the same case with more than two or three lasers arranged on said carriage 10, more than one group of lasers with one second laser and at least one conditioning laser per group can be arranged on said carriage 10 along parallel lines. This allows for scribing one groove per group of lasers during one movement of said carriage 10 along said movement direction 18.

According to the invention, it is not compulsory that said transparent insulator substrate 2 is mounted on said table-like arrangement 16 with a horizontal orientation with said film on its lower main surface. It is also possible to mount said transparent insulator substrate 2 on said table-like arrangement 16 with said film on its upper main surface. Furthermore, it is possible to arrange said carriage 10 below said transparent insulator substrate 2 in said gap 25 of said table-like arrangement 16 and to irradiate a light of the lasers from below on said film.

Further, it is not a requirement that either one of said first conditioning laser 11, second laser 12 or further conditioning laser 13 is mounted on said carriage 10 as described above. It is as well possible to mount these lasers in a fixed position sidewise to said table-like arrangement 16 and to guide said light of the lasers by a fibre or a mirror system to said carriage 10 and to direct said light from there on said film. Additionally, it is not required to have said carriage 10 moveable along said movement direction 18. In contrast, it is as well possible to mount said carriage in a fixed position above or below said transparent insulator substrate 2 and to guide said light of the lasers on said film along said movement direction 18.

The table-like arrangement shown in FIG. 4 and disclosed in WO 2005/118440 A1 is a preferred embodiment of the invention. Nonetheless, there are other embodiments of a table-like arrangement which provide the same functionality which can be used as an embodiment of the invention.

In summary, it is to be noted that the invention provides a method for dividing a semiconductor film formed on a substrate into plural regions by multiple laser beam irradiation that allows to lower the power of the used laser systems and that reduces or even avoids laser-caused problems which are known to occur in zones adjacent to laser-treated parts of materials.

What is claimed is:

1. A method for dividing a semiconductor film formed on a substrate into plural regions by multiple laser beam irradiation using a sequence of at least two laser beam treatments affecting essentially a same area of said film, wherein except of a final laser beam treatment, the treatments of said sequence of at least two laser beam treatments are used for a conditioning of the treated film area which is to be removed and in that said final laser beam treatment is applied to actually remove material in order to form a groove, wherein a first conditioning laser which is mounted on a carriage is used to perform a conditioning step and a second laser which is mounted on said carriage and which is arranged spaced apart of said first conditioning laser in a line oriented along a movement direction of said carriage is used to perform a removal step and in that a bidirectional functionality of the laser arrangement is achieved by using a further conditioning laser installed on said carriage in said line with said first conditioning and said second laser.

2. The method of claim 1, wherein except of said final laser beam treatment, essentially no matter shall be removed via ablation/evaporation by previous treatments of said sequence of said at least two laser beam treatments.

3. The method of claim 1, wherein a first laser beam treatment is followed by a second, third and so on within a time window of 0.01 to 1000 ms, preferably 0.1 to 100 ms.

4. The method of claim 1, wherein a first conditioning laser beam is generated by a continuous wave laser and in that a second laser beam is generated by a pulsed laser.

5. The method of claim 1, wherein said substrate is moved in one direction on a table-like arrangement for supporting said substrate.

6. (canceled)

7. (canceled)

8. The method of claim 5, wherein any region of said substrate is treated by moving said substrate on said table-like arrangement along said one direction and by moving said carriage with the laser arrangement along said movement direction which is oriented crosswise to said one direction.

9. The method of claim 8, wherein said groove is made parallel to said movement direction and said line.

10. The method of claim 1, wherein a laser beam is irradiated from another main surface of said substrate which is light transmissive, through said substrate to said same area of the respective said film, thus dividing/segmenting said film into said plurality of regions.

11. The method of claim 1, wherein said groove is made in said film in that said carriage is moved along said movement direction in either direction and said second laser and the one of said first conditioning laser and said further conditioning laser which is in front of said second laser as seen in the moving direction of said carriage are running, such that any point on said same area of said film, where said groove is to be made, is first treated with either said first conditioning laser or said further conditioning laser and subsequently treated with said second laser.

12. An arrangement for dividing a semiconductor film formed on a substrate into plural regions by multiple laser beam irradiation using a sequence of at least two laser beam treatments affecting essentially a same area of said film, comprising a first conditioning laser for the treatments of said sequence of at least two laser beam treatments except of a final laser beam treatment and comprising a second laser for said final laser beam treatment, wherein said arrangement comprises a carriage accommodating a plurality of lasers, comprising at least said first conditioning laser and, spaced apart but arranged in a line with a movement direction of the first conditioning laser, said second laser and in that said carriage can comprise a further conditioning laser arranged in said line with said first conditioning laser and said second laser in order to allow for a bidirectional functionality of said laser arrangement.

13. The arrangement of claim 12, wherein said substrate is moveable in one direction on a table-like arrangement for supporting said substrate.

14. (canceled)

15. (canceled)

16. The arrangement of claim 12, wherein said first conditioning laser is a continuous wave laser and in that said second laser is a pulsed laser.

17. The arrangement of claim 12, wherein said first conditioning laser and said further conditioning laser are identical and in that said first conditioning laser and said further conditioning laser are located at the same distance but in the opposite direction of said second laser.

18. The arrangement of claim 13, wherein any region of said substrate is treatable by moving said substrate on said table-like arrangement along said one direction and by moving said carriage with the laser arrangement along said movement direction which is oriented crosswise do said one direction.
